(19) United States
(12) Patent Application Publication
(10) Pub. No.: US 2004/0253830 A1
(43) Pub. Date: Dec. 16, 2004

(54) [METHOD FOR REMOVING SILICON NITRIDE FILM]

(76) Inventor: CHING-YU CHANG, YILAN HSIEN (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/250,185

(22) Filed: Jun. 11, 2003

(51) Int. Cl. H01L 21/302; H01L 21/461

(52) U.S. Cl. 438/745; 438/757

(57) ABSTRACT

A method for removing a silicon nitride film from a wafer is described. A wafer is provided having a silicon nitride film formed thereon, wherein the silicon nitride film exposes portions of the wafer surface. To remove the silicon nitride film, the wafer is put into an etching tank, into which phosphoric acid and an additive containing an oxidant have been introduced. During the removing process, an oxidation film is simultaneously formed on the portion of the wafer exposed by the silicon nitride film to protect the exposed portion from being damaged.

### BACKGROUND OF INVENTION

1. Field of the Invention

The present invention relates to an etching process. More particularly, the present invention relates to a method for removing a silicon nitride film.

2. Description of the Related Art

Among various processes in semiconductor fabrication, an etching process is conducted to remove a portion of a film exposed by a photoresist layer or a mask layer. Usually, a chemical method or a physical method is used to remove the exposed portion of a film, so that the patterns of a photo-mask can be transformed to the film. An etching process is also capable of removing a whole layer from a substrate. Current etching methods can be grouped into two wet etching and dry etching. In a wet etching process, the unwanted portion is removed via chemical reactions.

Since a silicon nitride film is usually used as a mask layer during semiconductor fabrication, processes of removing silicon nitride films are frequently performed. Usually, phosphoric acid is used to remove a silicon nitride film, and a wafer is put in a phosphoric acid tank in a silicon nitride etching process. During the process, water is introduced to the phosphoric acid tank from the bottom thereof to dilute the concentrated phosphoric acid, and the silicon nitride film is etched by the diluted phosphoric acid and removed.

However, if the etching process is not controlled properly and precisely, the wafer is easily damaged. Particularly, when a silicon nitride film used as a mask for ion implantation is being removed, the wafer surface is much more easily damaged because the previous ion implantation has weakened the wafer surface. The detail descriptions a conventional silicon nitride etching process are as follows.

Please refer to FIGS. 1A to 1C, which illustrate the steps from ion implantation to silicon nitride removal in the prior art in a cross-sectional view. As shown in FIG. 1A, a pad oxide layer 102 has been formed on a substrate 100, and a patterned silicon nitride film 104 has been formed on the pad oxide layer 120. The silicon nitride film 140 is used as an implantation mask of the substrate 100, and an ion implantation 106 is applied to the substrate 100 to form a doped region 108.

The high energy of the ion implantation 106 damages the lattice structure of the exposed pad oxide layer 102 and lower the strength of the exposed pad oxide layer 102. After the doped region 108 is formed, a silicon nitride removing process is implemented, as illustrated in FIGS. 1B to 1C. During the removing process of the silicon nitride film 104, the damaged portion of the pad oxide layer 102 will likely be dissolved before the silicon nitride film 104 is totally removed, so that the doped region 108 is exposed to the etching solution.

The high energy of the ion implantation 106 also reduces the stability of the doped region 108. Therefore, when the doped region 108 is exposed to the etching solution, notches or dimples 110 may be formed on the surface of the substrate 100, as depicted in FIG. 1C. The defects 110 will reduce the reliability of the circuit devices that are built on the substrate 100.

### SUMMARY OF INVENTION

Accordingly, the present invention provides a method for removing a silicon nitride film without damaging the wafer surface, so that the well-known problems that occur during removing a silicon nitride film can be solved.

The present invention is also provided to avoid damages on an integrated circuit that uses a silicon nitride film as a mask layer during its fabrication. Particularly, the method of the present invention can avoid damages caused by removal of a silicon nitride film after an ion implantation. The method for removing a silicon nitride film of the present invention includes the following steps. A phosphoric acid tank equipped with a water pump unit is provided. An additive containing an oxidant is added to the phosphoric acid tank. The additive can be a solution containing hydrogen peroxide, a solution containing ozone, or a gas containing ozone. The additive is introduced into the phosphoric acid tank via the water pump or an additional pipeline and another pump. After the additive has been added to the phosphoric acid tank, the wafer is put into the tank for removing the silicon nitride film from the wafer. The oxidant in the additive will react with the wafer surface exposed by the silicon nitride film to form an oxidation film thereon. This oxidation film can protect the wafer surface from being damaged in the etching process.

Since the present invention forms an oxidation film over the exposed portions during removal of the silicon nitride film, the wafer surface can be protected from being damaged in the etching process. Accordingly, the present invention does solve the problems that are frequently encountered in removing a silicon nitride film from a wafer.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A to 1C illustrate the steps from ion implantation to silicon nitride removal in the prior art in a cross-sectional view, wherein FIG. 1C illustrates several dimples and notches formed on the surface of the wafer.

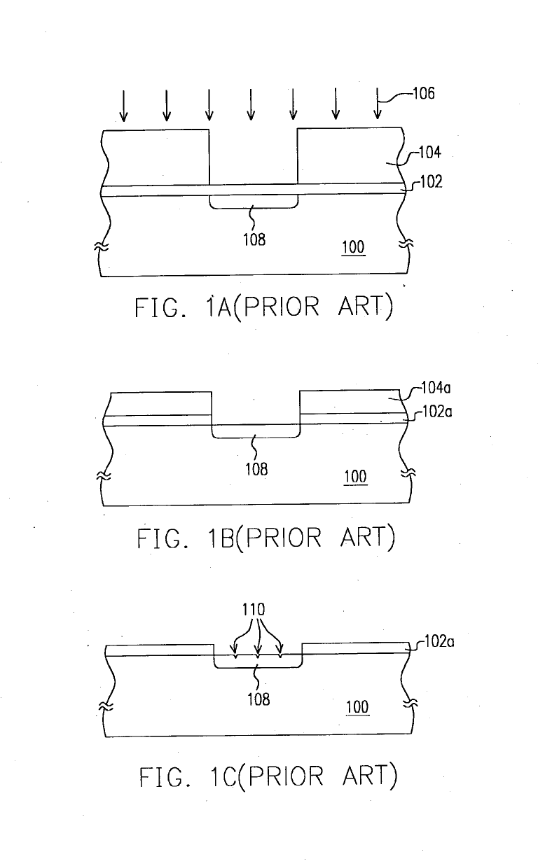

FIG. 2 illustrates an apparatus for removing a silicon nitride film from a wafer according to a preferred embodiment of the present invention.

FIG. 3 illustrates another apparatus for removing a silicon nitride film from a wafer according to the preferred embodiment of the present invention.

FIGS. 4A to 4C illustrate a process flow of removing a silicon nitride film from a wafer according to the preferred embodiment in a cross-sectional view.

### DETAILED DESCRIPTION

Reference will now be made in detail to the preferred embodiment of the invention, examples of which are illustrated in the accompanying drawings. Wherever possible, the same reference numbers are used in the drawings and the description to refer to the same or like parts.

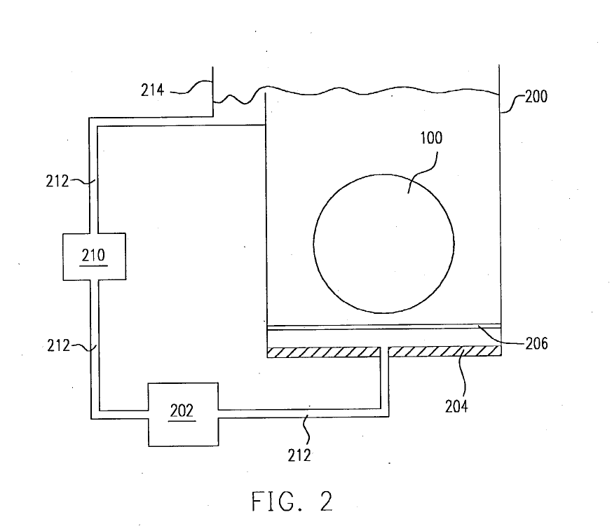

FIG. 2 illustrates an apparatus for removing a silicon nitride film from a wafer according to the preferred embodiment of the present The apparatus consists of a phosphoric acid tank 200, a water pump unit 202, a pipeline 212, a heating pad 204, and a plate 206 that separates the tank 200 into upper and lower parts.

The phosphoric acid tank 200 contains concentrated phosphoric acid. Phosphoric acid of 86% in concentration usually found in the market can be used in the etching process. The phosphoric acid tank 200 and the water pump unit 202 are connected via a pipeline 212, and the other end of the water pump unit 202 is connected to another pump 210 via the pipeline 212. One end of the pipeline 212 is connected to the bottom of the phosphoric acid tank 200. The water pump unit 202 can be controlled to precisely add a certain amount of water at a certain moment to the phosphoric acid tank 200.

In this application, the phosphoric acid tank 200 can be designed as an overflow tank. The phosphoric acid that overflows from the phosphoric acid tank 200 is collected in a collection tank 214. Via the pipeline 212 and the pump 210, the phosphoric acid in the collection tank 214 can be recycled and returned back to the phosphoric acid tank 200.

The heating pad 204 is mounted on the bottom of the phosphoric acid tank 200 to keep the phosphoric acid tank 200 at a constant temperature, preferably at about 160 Å C.

The plate 206 is installed around the bottom of the phosphoric acid tank 200. The plate 206 is drilled with many small holes that are small enough to have the water spread evenly in the phosphoric acid tank 200 and fully mix with the phosphoric acid. Through the plate 206, a well-mixed phosphoric acid solution is allowed to reach the wafer that is put in the phosphoric acid tank 200.

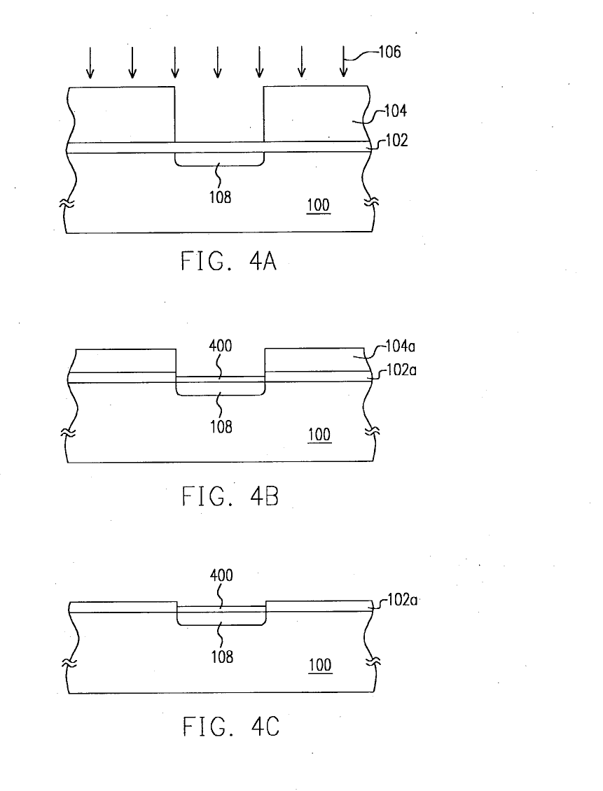

The use of the apparatus depicted in FIG. 2 to remove a silicon nitride film is described as follows with reference to FIGS. 4A-4C. As illustrated in FIG. 4A, a silicon nitride film 104 that acts as an implantation mask has been grown on a wafer 100. Usually, before the silicon nitride film 104 is formed, a pad oxide film 102 is grown on the wafer 100. An ion implantation 106 has been applied to the wafer 100 to form a doped region 108 after the silicon nitride film 104 is grown on the wafer 100. After the ion implantation 106 is performed, the silicon nitride film 104 is ready to be removed.

The process for removing the silicon nitride film 104 is described as follows. The wafer 100 is put into the phosphoric acid tank 200, into which phosphoric acid and an additive containing an oxidant have been introduced.

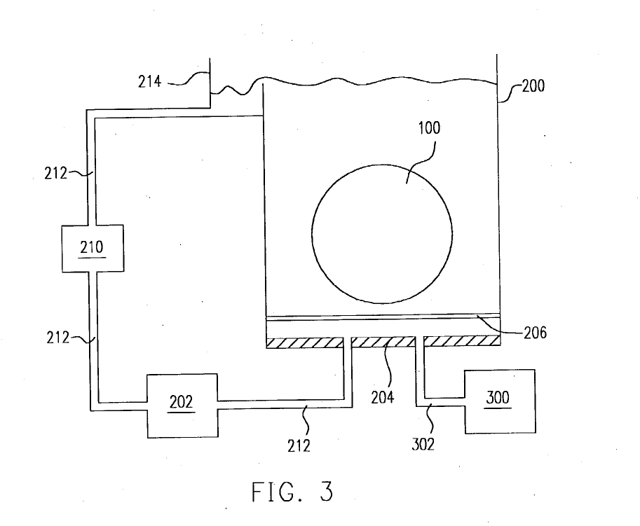

In the preferred embodiment of the present invention, the additive containing an oxidant can be a solution containing hydrogen peroxide, a solution containing ozone, or a gas containing ozone. The additive is introduced into the phosphoric acid tank 200 via the water pump 202 (FIG. 2), or via an additional pipeline 302 and another pump 300 (FIG. 3).

Referring to FIG. 4B, during the silicon nitride removing process, the wafer 100 is put into the phosphoric acid tank 200, wherein the exposed pad oxide 102a that has been weakened by the ion implantation 106 is easily removed so that the wafer surface originally under the exposed pad oxide 102a gets exposed. At this moment, a chemical reaction triggered by the oxidant grows an oxidation film 400 on the exposed surface of the wafer 100. The oxidation film 400 can protect the exposed surface of the wafer 100 from being damaged in the silicon nitride etching process.

It is worth to mention that the oxidation film 400 is more stable than the exposed pad oxide 102a that has been weakened by the ion implantation 106, so the oxidation film 400 can effectively protect the surface of the wafer 100 from being damaged by the etchant.

FIG. 4C depicts the structure of the wafer 100 after the silicon nitride removing process is finished. FIG. 4C shows that the doped region 108 is undamaged due to the protection of the oxidation film 400.

Since the present invention forms an oxidation film over the exposed portion of the substrate during removal of the silicon nitride film, the wafer can be protected from being damaged in the etching process. Accordingly, the present invention can solve the problems that are usually encountered in removing a silicon nitride film from a wafer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A method for removing a silicon nitride film, comprising the steps of:
providing a wafer having a silicon nitride film thereon, the silicon nitride film exposing a portion of the wafer;
putting the wafer into an etching tank where an etchant and an additive containing an oxidant have been introduced into, so as to remove the silicon nitride film and to simultaneously form an oxidation film over the portion of the wafer exposed by the silicon nitride film.

2. The method of claim 1, wherein the additive containing an oxidant comprises a solution containing hydrogen peroxide.

3. The method of claim 1, wherein the additive containing an oxidant comprises a solution containing ozone.

4. The method of claim 1, wherein the additive containing an oxidant comprises a gas containing ozone.

5. The method of claim 1, wherein the etchant comprises phosphoric acid.

6. The method of claim 1, wherein a pad oxide film has been grown on the wafer prior to the silicon nitride film.

7. The method of claim 1, wherein the wafer having a silicon nitride film thereon has been subjected to an ion implantation.

8. A method for removing a silicon nitride film, comprising:
providing a phosphoric acid tank that is equipped with a water pump unit the phosphoric acid tank having phosphoric acid therein;
introducing an additive containing an oxidant into the phosphoric acid tank;
providing a wafer having a silicon nitride film thereon, the silicon nitride film exposing a portion of the wafer; and
putting the wafer in the phosphoric acid tank to remove the silicon nitride film and to simultaneously form an oxidation film over the portion of the wafer exposed by the silicon nitride film.

9. The method of claim 8, wherein the additive containing an oxidant comprises a solution containing hydrogen peroxide.

10. The method of claim 8, wherein the additive containing an oxidant comprises a solution containing ozone.

11. The method of claim 8, wherein the additive containing an oxidant comprises a gas containing ozone.

12. The method of claim 8, wherein the additive is introduced into the phosphoric acid tank via the water pump unit.

13. The method of claim 8, wherein the additive is introduced into the phosphoric acid tank via a set of pipeline and another pump.

14. The method of claim 8, wherein a pad oxide film has been grown on the prior to the silicon nitride film.

15. The method of claim 8, wherein the wafer having the silicon nitride film thereon has been subjected to an ion implantation.
